(19) United States
(12) Patent Application Publication
(10) Pub. No.: US 2010/0216411 A1
(43) Pub. Date: Aug. 26, 2010

(54) MICROWAVE AND/OR MILLIMETER-WAVE BAND AMPLIFIER CIRCUIT, AND MILLIMETER-WAVE TRANSCEIVER USING THEM

(75) Inventor: Naoyuki KURITA, Kokubunji (JP)

Correspondence Address: MATTINGLY & MALUR, P.C., 1800 DIAGONAL ROAD, SUITE 370, ALEXANDRIA, VA, 22314, US

(73) Assignee: HITACHI, LTD., Tokyo (JP)

(21) Appl. No.: 12/705,996

(22) Filed: Feb. 16, 2010

(30) Foreign Application Priority Data
Feb. 26, 2009 (JP) 2009-043982

(51) Int. Cl. H04B 1/40; H03F 3/191

(52) U.S. Cl. 455/75; 330/306

(57) ABSTRACT

An amplifier circuit having a flat gain over a wide bandwidth in a high frequency region which is proximate to a maximum oscillating frequency fₘₐₓ of each transistor and which has a small degree of allowance in terms of performance thereof. The circuit configuration uses lossless elements only since the use of a resistor element in a matching circuit is avoided to prevent significant losses from being incurred. The amplifier circuit has “n” stages wherein the transistors are arranged in cascade connection in a fashion that the sizes of the transistors are incremented successively in the direction from input to output, and wherein matching circuits are arranged to provide a high-pass frequency characteristic in a fashion that cut-off frequencies f₁, f₂, . . . , and fₙ (low band cut-off frequencies) are decremented successively in the direction from input to output.

### CLAIM OF PRIORITY

The present application claims priority from Japanese Patent Application 2009-43982 filed on Feb. 26, 2009, the content of which is hereby incorporated by reference into this application.

### FIELD OF THE INVENTION

The present invention relates to a microwave and/or millimeter-wave band amplifier circuit having a function for amplifying high-frequency signals belonging to the microwave band and/or the millimeter-wave band, and also relates to a millimeter-wave transceiver using the same.

### BACKGROUND OF THE INVENTION

Regarding microwave frequencies ranging from approximately 3 GHz to 30 GHz and millimeter-wave frequencies exceeding 30 GHz, available frequency bands thereof are not yet scarce in frequency band allocation unlike the case of other lower frequencies. In the range of the microwave and millimeter-wave frequencies, an adequately wide band is assignable for a particular purpose of use. Hence, intensive research and development activities are being carried out to produce microwave and millimeter-wave transmitting/receiving circuits through use of various semiconductor device fabrication processes, with expectation of applications to high-speed broadband communication systems or the like.

For practical application of an amplifier circuit having a transmission signal amplifying function to a broadband communication system, it is required to provide a flat gain over the entire frequency range corresponding to the band concerned. The following conventional arrangements for bandwidth broadening with respect to gain in amplifier circuit design are well known; a negative-feedback type of amplifier circuit arrangement shown in FIG. 14, and a resistive-matching type of amplifier circuit arrangement shown in FIG. 15 (proposed in the non-patent document “MMIC TECHNOLOGY BASICS & APPLICATIONS” coauthored by Y. Ito and T. Takagi, published by REALIZE INC., 1996 May 31, p. 133, line 17 to p. 137, line 9).

Referring to FIG. 14, there is shown a circuit diagram of an exemplary conventional negative-feedback type of amplifier circuit, which has a two-stage configuration comprising transistors 11 and 12 used as amplifying elements. For operation of the transistors 11 and 12, circuits 73 and 74 are disposed to supply bias source voltages V_{d} and V_{g} to a drain port and a gate port of each of the transistors 11 and 12. In this negative-feedback-type amplifier circuit, a resistor 61 is inserted between the gate and drain ports of the transistor 61, and a source port of each transistor is grounded via a resistor 62. Thus, a part of a signal to be amplified through propagation in the direction from input to output is fed back to the input side for the purpose of providing flatness in gain in the entire amplifier circuit. It is to be noted that a capacitor 75 is inserted to block a direct current from a bias power source in such a fashion as to provide a capacitor value having no effect on operational performance of the amplifier circuit.

Referring to FIG. 15, there is shown a circuit diagram of an exemplary conventional resistive-matching type of amplifier circuit. In this resistive-matching-type amplifier circuit, a resistor element 71 or 72 is inserted between ground and a gate or drain port of transistors 11 and 12. Thus, a part of a signal to be amplified through propagation in the direction of input to output is fed to ground to ensure stable transistor operation for the purpose of providing flatness in gain in the entire amplifier circuit. It is to be noted that a capacitor 75 is inserted to block a direct current from a bias power source in such a fashion as to provide a capacitor value having no effect on operational performance of the amplifier circuit.

In Japanese Patent Application Laid-Open Publication No. 2003-92520, there is disclosed an amplifier circuit including plural transistors arranged at multiple stages in cascade connection wherein a center frequency of each inter-stage matching circuit is intentionally shifted in design and a center frequency of a matching circuit at the last stage is arranged to be set at the center of a desired frequency band, thus aiming at bandwidth broadening with respect to gain in the entire amplifier circuit.

Further, Japanese Patent Application Laid-Open Publication No. 2008-85929 discloses an arrangement in which plural power amplifier stages are configured for bandwidth broadening in power amplification of signals belonging to plural frequency bands.

Still further, Japanese Patent Application Laid-Open Publication No. 2008-104221 discloses an exemplary multiple-stage cascade-connection amplifier wherein the sizes of elements thereof are arranged to increase in a monotonous fashion for operation in combination with changeover switches for selection of signals having different frequencies, with the aim of combinational use of schemes of different frequency bands.

### SUMMARY OF THE INVENTION

In either of the conventional arrangements shown in FIGS. 14 and 15, resistor elements are added to certain locations in the amplifier circuit for the purpose of providing flatness in gain therein. However, since the degree of loss due to the added resistor elements is significantly large, there occurs a problematic decrease in the ratio of an amplification factor possessed by each transistor proper to an amplification factor of the entire amplifier circuit in terms of reflection therein. It is therefore difficult to ensure a satisfactory gain in application of either of the conventional arrangements shown in FIGS. 14 and 15 to the designing of a microwave and/or millimeter-wave band amplifier circuit having an operating frequency proximate to a maximum oscillating frequency fₘₐₓ that allows each transistor to ensure an amplifying function thereof.

Being different from the conventional arrangements exemplified in FIGS. 14 and 15, a technique for providing flatness in gain by using lossless elements only in lieu of resistor elements is proposed in Japanese Patent Application Laid-Open Publication No. 2003-92520.

It is to be noted, however, that a matching circuit assumed in Japanese Patent Application Laid-Open Publication No. 2003-92520 has a bandpass frequency characteristic that enables provision of a desired characteristic in the vicinity of the center of a frequency band in use. In the matching circuit, it is required to use a circuit element for cutting off a transmission signal on both the lower and higher frequency regions. Hence, the number of circuit elements required increases inevitably, and in the microwave and/or millimeter-wave band including significantly high frequencies, even a small amount of loss due to an increase in the number of circuit elements is likely to bring about an adverse effect on the gain of the amplifier circuit concerned.

In Japanese Patent Application Laid-Open Publication No. 2008-85929, a multiple-stage power amplifier shown in FIG. 1(B) therein is described with the following argument; “Even in cases where the same active element is used, the frequency range of maximum gain Amax in terms of frequency-gain characteristic tends to narrow for a large signal level though it is allowed to widen the frequency range of maximum gain Amax for a small signal level. From this point of view, it is recommended that an amplification factor of a preceding-stage power amplifier AMP having a small signal level should be larger than that of a succeeding-stage power amplifier AMP in consideration of advantageousness in bandwidth broadening in the entire arrangement”. That is, there is disclosed such a design concept that a frequency at the first-stage power amplifier should be higher while a frequency at the last-stage power amplifier should be lower. In Japanese Patent Application laid-Open Publication No. 2008-85929, it is proposed to use a switch circuit for path changeover for the purpose of circumventing difficulty in the designing of a matching circuit for a multiple-stage power amplifier.

However, including the case of the arrangement disclosed in Japanese Patent Application Laid-Open Publication No. 2008-104221, the use of such a changeover switch gives rise to an disadvantage in that it is difficult to achieve a higher speed of device operation and a reduction in device size.

It is therefore an object of the present invention to provide a microwave and/or millimeter-wave band amplifier circuit and a millimeter-wave transceiver using the same which having an operating frequency region which is proximate to a maximum oscillating frequency fₘₐₓ allowing each transistor to ensure an amplifying function thereof while having a small degree of allowance in terms of performance thereof, and capable of achieving a higher speed of device operation without a substantial increase in device size, wherein a sufficient degree of flat gain can be obtained over a wide bandwidth

In accordance with a representative configurational aspect of the present invention, there is provided an amplifier circuit suitable for amplifying at least either microwave band signal or millimeter-wave band signal, the amplifier circuit comprising: a plurality of transistors disposed at a plurality of stages in a direction from input to output; and a plurality of matching circuits for coupling the transistors in cascade connection, wherein the transistors each have different maximum oscillating frequencies, wherein the sizes of the transistors are arranged to be incremented successively in the direction from input to output, wherein each of the matching circuits for coupling the transistors provides a high-pass frequency characteristic, wherein the matching circuits being arranged in a fashion that each of a low band cut-off frequency of the high-pass frequency characteristic thereof is decremented successively in the direction from input to output, wherein a gain in the amplifier circuit has a bandpass frequency characteristic, and wherein a gain restricting characteristic on the higher frequency side of the bandpass frequency characteristic is implemented based on a frequency characteristic of each of the transistors, and a gain restricting characteristic on the lower frequency side thereof is implemented based on the cut-off frequency of each of the matching circuits.

According to the present invention, a small-type microwave and millimeter-wave band amplifier circuit and a millimeter-wave transceiver using the same capable of performing higher-speed operation can be provided in a simple circuit configuration without resorting to a changeover switch or the like.

The above and other objects, features and advantages of the present invention will become more apparent from the following detailed description with reference to the accompanying drawings.

### BRIEF DESCRIPTION OF THE DRAWINGS

FIG. 1 is an explanatory pattern diagram of frequency characteristics with respect to transistor gain values;

FIG. 2 is a schematic block diagram showing the basic configuration and frequency characteristics with respect to gain values according to the present invention;

FIG. 3 is a graphical representation showing the basic principle and frequency characteristics with respect to gain values according to the present invention;

FIG. 4 is a circuit diagram of an amplifier according to a first preferred embodiment of the present invention;

FIG. 5 is a graphical representation showing the frequency characteristics with respect to transistor gain values in the amplifier according to the first preferred embodiment of the present invention;

FIG. 6 is a graphical representation showing the frequency characteristics of inter-stage matching circuits in the amplifier according to the first preferred embodiment of the present invention;

FIG. 7 is a graphical representation showing the composite frequency characteristics in combinations of the frequency characteristics of the inter-stage matching circuits and transistors in the amplifier according to the first preferred embodiment of the present invention;

FIG. 8 is a graphical representation showing the frequency characteristic with respect to gain of the entire amplifier according to the first preferred embodiment of the present invention;

FIG. 9 is a circuit diagram of an amplifier according to a second preferred embodiment of the present invention;

FIG. 10 is a graphical representation showing the frequency characteristics with respect to gain values of GaAs field-effect transistors (high electron mobility transistors: HEMTs) having different gate widths W_{g};

FIG. 11 is a graphical representation showing frequency characteristics with respect to gain values of SiGe bipolar transistors having different emitter areas;

FIG. 12 is a schematic diagram showing an exemplary configuration of a millimeter-wave transceiver including an amplifier circuit according to the present invention;

FIGS. 13A and 13B are diagrammatic illustrations showing an exemplary RF module including the millimeter-wave transceiver in FIG. 12;

FIG. 14 is a circuit diagram of an amplifier in a first exemplary conventional arrangement; and

FIG. 15 is a circuit diagram of an amplifier in a second exemplary conventional arrangement.

### DETAILED DESCRIPTION OF THE PREFERRED EMBODIMENTS

According to an aspect of the present invention, there is provided a featured amplifier circuit configuration having plural stages disposed in cascade connection wherein the sizes of transistors thereof are arranged to be incremented successively in the input-to-output-stage direction, wherein each of plural inter-stage matching circuits for coupling the transistors has a high-pass frequency characteristic for filtering in functional propagation of a signal to be amplified in the input-to-output-stage direction, and wherein low band cut-off frequencies thereof are arranged to be decremented successively in the input-to-output-stage direction.

The present invention will now be described in detail by way of example with reference to the accompanying drawings.

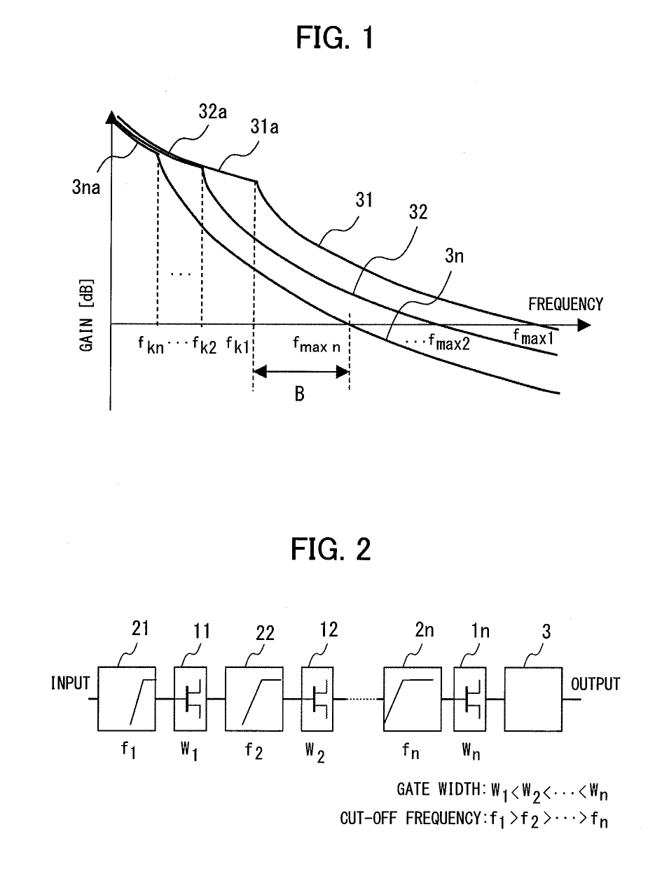

FIG. 1 is an explanatory pattern diagram regarding an amplifier circuit including plural transistors arranged in cascade connection, showing frequency characteristics with respect to maximum available power gain Gₐₘₐₓ values and maximum stable power gain Gₘₛ values of the transistors having different sizes used at the first, second, . . . , and n-th stages of the amplifier circuit. In FIG. 1, reference numeral 31 indicates the frequency characteristic with respect to a maximum available power gain Gₐₘₐₓ of the first stage transistor, reference numeral 32 indicates the frequency characteristic with respect to a maximum available power gain Gₐₘₐₓ of the second stage transistor, and reference numeral 3n indicates the frequency characteristic with respect to a maximum available power gain Gₐₘₐₓ of the n-th stage transistor. Reference numeral 31a indicates the frequency characteristic with respect to a maximum stable power gain Gₘₛ of the first stage transistor, reference numeral 32a indicates the frequency characteristic with respect to a maximum stable power gain Gₘₛ of the second stage transistor, and reference numeral 3na indicates the frequency characteristic with respect to a maximum stable power gain Gₘₛ of the n-th stage transistor.

With an increase in transistor size, capacitive and inductive parasitic components are increased to decrease a maximum oscillating frequency fₘₐₓ corresponding to a Gₐₘₐₓ value of 0 dB, causing degradation in transistor performance in common applications. As shown in FIG. 1, the frequency characteristic 31 with respect to the maximum available power gain Gₐₘₐₓ of the first stage transistor and the frequency characteristic 31a with respect to the maximum stable power gain Gₘₛ thereof have the highest level of performance. Since the sizes of the second stage and n-th stage transistors are arranged to be incremented in successive order, the frequency characteristics 32 and 32a of the second stage transistor and the frequency characteristics 3n and 3na have lower performance levels than those of the first stage transistor accordingly.

In designing a transmission power amplifier for a wireless transmitter-receiver system, it is common practice to employ a configurational arrangement in which the sizes of transistors used are incremented in successive order in the direction from input to output for the purpose of obtaining larger output power. The frequency characteristics with respect to the maximum available power gain Gₐₘₐₓ and maximum stable power gain Gₘₛ can be expressed by the following equations (1) to (3) using four scattering parameter (S parameter) components S₁₁, S₁₂, S₂₁, and S₂₂ of a transistor. It is to be noted here that these S parameter components are indicated as functions of frequency.

$$\begin{matrix}{G}_{amax} = \vert \frac{{S}_{21}}{{S}_{12}} \vert ( K - \sqrt{{K}^{2} - 1} ) & ( 1 ) \\ K = \frac{1 + {\vert {S}_{11} {S}_{22} - {S}_{12} {S}_{21} \vert}^{2} - {\vert {S}_{11} \vert}^{2} - {\vert {S}_{22} \vert}^{2}}{2 \vert {S}_{12} {S}_{21} \vert} & ( 2 ) \\ {G}_{ms} = \vert \frac{{S}_{21}}{{S}_{12}} \vert & ( 3 )\end{matrix}$$

In equation (2), “K” stands for a stability factor. In a frequency range of K>1 with respect to the maximum available power gain Gₐₘₐₓ defined by equation (1), the transistor concerned is put in an unconditionally stable state wherein the transistor can perform stable amplifying operation even if a passive element having an arbitrary impedance is connected thereto. Contrastingly, in a frequency range of K<1, the maximum available power gain Gₐₘₐₓ is not real-valued, and a gain value of the transistor is defined by the maximum stable power gain Gₘₛ represented by equation (3) for the sake of convenience. In the frequency range of K<1 noted above, the transistor is put in a conditionally stable state wherein the transistor may become unstable depending on an impedance value of a passive element connected thereto to bring about parasitic oscillation, causing hindrance to stable amplifying operation. Hence, in common practice of designing an amplifier for the frequency range of K<1, a circuit element such as a resistor is connected in the vicinity of a transistor to decrease a gain value thereof for providing a stable state satisfying the condition where K>1. For convenience in description of the present invention, a frequency of K=1 is defined as a stable function frequency fₖ, and the stable function frequencies of the first stage to n-th stage transistors are designated as fₖ₁, fₖ₂, and fₖₙ as shown in FIG. 1.

In the present invention, it is assumed that an amplifier circuit is operated a high frequency range proximate to the maximum oscillating frequency fₘₐₓ of each transistor used therein. More specifically, as shown in FIG. 1, the amplifier circuit of the present invention is suitable for applications in a frequency range B between the lowest level corresponding to a maximum oscillating frequency fₘₐₓₙ of the n-th stage transistor and the highest level corresponding to a maximum stable operating frequency fₖ₁ of the first stage transistor. It is to be noted, however, that a bandpass frequency characteristic is designed in practice so as to provide a substantially flat gain form in a frequency range narrower than the range B to some extent, i.e., in a frequency range between the maximum oscillating frequency fₘₐₓₙ of the n-th (last) stage transistor and a minimum cut-off frequency of an output-side matching circuit, as will be described more fully in regard to a preferred embodiment to be presented later.

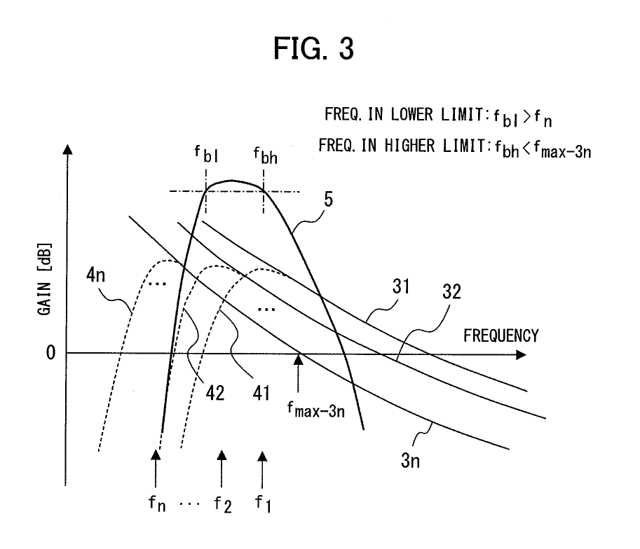

With reference to FIGS. 2 and 3, the following describes the configurational arrangement and frequency characteristics with respect to gain values of a microwave and/or millimeter-wave band amplifier circuit which comprises “n” transistors having different sizes arranged in cascade connection.

FIG. 2 shows a schematic block diagram of the basic configuration of the amplifier circuit according to the present invention. In the amplifier circuit, transistors 11, 12, . . . , and 1n, i.e., “n” transistors are arranged in cascade connection. At the position immediately preceding each of the transistors, there is disposed each of plural matching circuits 21, 22, . . . , 2n for performing impedance matching and for transmitting amplified signals while suppressing transmission loss. In common practice of designing a power amplifier for which a high output power is required, a matching circuit 3 at an output part is so arranged as to perform matching with the degree of impedance that allows the highest level of output power.

Here, the sizes of the transistors 11, 12, . . . , and 1n are denoted as W₁, W₂, . . . , and Wₙ. Since the sizes of the transistors are arranged to be incremented in successive order in the direction from input to output, the following relationship is then established; W₁<W₂ . . . <Wₙ. In FIG. 3, the frequency characteristics with respect to Gₐₘₐₓ of the individual transistors are indicated as 31, 32, . . . , and 3n.

Each of the matching circuits 21, 22, . . . , 2n disposed at the position immediately preceding each of the transistors is designed to have a high-pass filter circuit configuration so as to provide each of a plurality of cut-off frequencies f₁, f₂, . . . , and fₙ that are decremented successively in the direction from input to output (f₁>f₂> . . . >fₙ). Regarding the frequency characteristic with respect to Gₐₘₐₓ of each transistor, since a lower frequency range is cut off through each of the matching circuits preceding thereto, there is provided each of plural frequency characteristics 41, 42, . . . , and 4n as indicated by the broken lines in FIG. 3.

Hence, a combination of the first stage transistor 11 and the matching circuit 21 provides a smoothly curved form including a pair of curve 41 and curve 31 as the frequency characteristic with respect to Gₐₘₐₓ thereof. Likewise, a combination of the second stage transistor 12 and the matching circuit 22 provides a smoothly curved form including a pair of curve 42 and curve 32, and a combination of the n-th stage transistor 1n and the matching circuit 2n provides a smoothly curved form including a pair of curve 4n and 3n. In the amplifier circuit including the first to n-th stage transistors and matching circuits arranged in cascade connection, an overall frequency characteristic with respect to gain thereof is represented as the sum of the individual frequency characteristics with respect to Gₐₘₐₓ corresponding to the above smoothly curved forms. That is, in the entire amplifier circuit, there is provided a composite frequency characteristic 5 indicated by the thick solid curved line in FIG. 3.

Without using a resistor element that is a possible cause of transmission loss, each inter-stage matching circuit is so configured as to have a reduced number of lossless elements of non-resistor types.

By properly selecting the characteristic and size of each of the transistors at the respective stages, determining the order of mutual connections thereof, and arranging circuits elements of the matching circuits 21, 22, . . . , and 2n in the above-mentioned fashion, it is possible to obtain a bandpass characteristic having a substantially flat gain form between a lower limit frequency f_{b1} and a higher limit frequency f_{bh} with respect to gain as indicated by the composite frequency characteristic 5, i.e., there can be provided a bandpass characteristic maintaining a substantially flat gain form in a certain frequency range. It is to be noted here that the lower limit frequency f_{b1} of the substantially flat gain form is higher than a level corresponding to the lowest cut-off frequency fₙ, and the higher limit frequency f_{bh} thereof is lower than a level corresponding to the maximum oscillating frequency fₘₐₓ₋₃ₙ of the last stage transistor.

In the present invention, the output matching circuit is designed on the basis that a priority is given to impedance matching for maximizing output power, thus not contributing to provision of a wideband frequency characteristic. However, in cases where it is not necessarily required to perform impedance matching for maximizing output power on account of allowance in terms of output power specified for the amplifier circuit 3, a high-pass filtering function may also be arranged in the output matching circuit 3 to allow the setting of a cut-off frequency lower than fₙ for contributing to provision of a wideband frequency characteristic in the amplifier circuit.

In the amplifier circuit of the present invention, gain cutting-off on the lower frequency side regarding the frequency characteristic with respect to bandpass filtering gain is implemented by using combinations of the cut-off frequencies f₁, f₂, . . . , and fₙ of the matching circuits.

Contrastingly, gain cutting-off on the higher frequency side in the amplifier circuit of the present invention is implemented by using the maximum oscillating frequency characteristic fₘₐₓₙ of each transistor proper, wherein Gₐₘₐₓ thereof decreases with an increase in frequency. More specifically, in a frequency range slightly exceeding the higher limit frequency f_{bh} of the bandpass characteristic, while the frequency characteristic gain of the first stage transistor is still larger than zero (0), the frequency characteristic gain of the last stage transistor becomes negative to bring about the effect of attenuation. Through combinational use of amplification and attenuation based on difference in maximum oscillating frequency characteristic among the transistors at the respective stages, the gain of the composite frequency characteristic 5 can be made to decrease steeply in the frequency range exceeding the higher limit frequency f_{bh} without resorting to a changeover switch or the like. Thus, an amplifier circuit that includes multiple-stage transistors having a bandpass characteristic can be realized.

As mentioned above, the maximum oscillating frequency characteristic fₘₐₓₙ of each transistor proper is utilized to provide the higher limit frequency f_{bh} of the bandpass characteristic concerned in the present invention. That is, according to an aspect of the present invention, a high frequency region which is proximate to the maximum oscillating frequency fₘₐₓ of each transistor and which has a small degree of allowance in terms of performance thereof is used advantageously to set up the higher limit frequency f_{bh} of the bandpass characteristic concerned. Thus, in a simple circuit configuration without using a changeover switch or the like, a higher speed of device operation can be realized while obviating a substantial increase in device size.

The following describes more specific embodiments of the present invention.

### First Preferred Embodiment

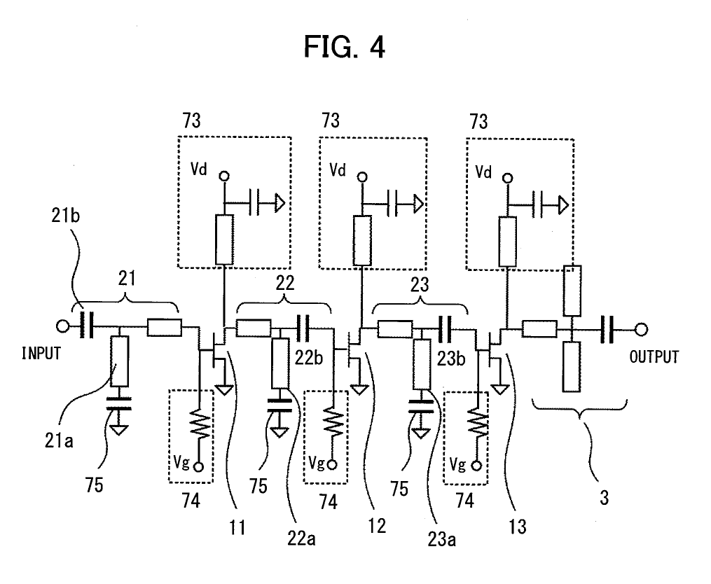

FIG. 4 shows a circuit diagram of an amplifier circuit according to a first preferred embodiment of the present invention. The amplifier circuit includes three stages of field-effect transistors 11, 12, and 13 arranged in cascade connection, and each transistor is coupled to bias circuits 73 and 74 for applying drain bias and gate bias voltages. In the first preferred embodiment of the present invention, the gate width W_{g} of the transistor 11 is 80 μm, the gate width W_{g} of the transistor 12 is 160 μm, and the gate width W_{g} of the transistor 13 is 320 μm. That is, the gate widths W_{g} of the transistors used in the amplifier circuit are arranged to be incremented at a ratio of 1:2:4 in the direction from input to output.

Further, an input matching circuit 21 is disposed at an input terminal position of the amplifier circuit, and an output matching circuit 3 is disposed at an output terminal position thereof. The adjacent transistors are coupled to each other via inter-stage matching circuits 22 and 23.

The input matching circuit 21, and the inter-stage matching circuits 22 and 23 includes series capacitors 21b, 22b and 23b, and short-stubs 21a, 22a and 23a formed of ground-connected microstrip lines, respectively, which are arranged to provide a high-pass frequency characteristic. It is allowed to adjust a cut-off frequency through use of a combination of the capacitance of each series capacitor and the length of each short-stub. The output matching circuit 3 is designed with a priority given to conditions required for maximizing output power. Having a microstrip line and an open-stub in combination, the output matching circuit 3 is arranged not to contribute to provision of a wideband characteristic in the amplifier circuit. It is to be noted that a capacitor 75 is provided to block a direct current from a bias power source in such a fashion as to provide a capacitor value having no effect on operational performance of the amplifier circuit.

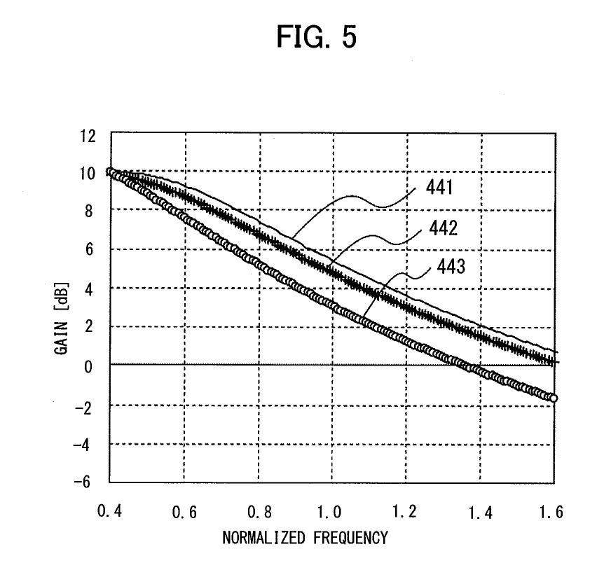

FIG. 5 shows the frequency characteristics with respect to transistor gain values in the amplifier according to the first preferred embodiment of the present invention. In FIG. 5, reference numeral 441 indicates the frequency characteristic of the first stage transistor 11 in the amplifier circuit, reference numeral 442 indicates the frequency characteristic of the second stage transistor 12, and reference numeral 443 indicates the frequency characteristic of the third stage transistor 13.

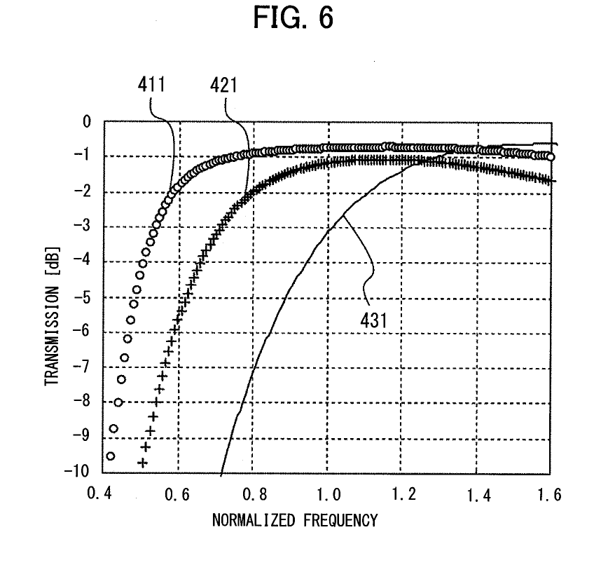

FIG. 6 shows the frequency characteristics with respect to transmission values of the respective matching circuits. In FIG. 6, the characteristic of the input matching circuit 21 is indicated by a curved line 411, the characteristic of the inter-stage matching circuit 22 is indicated by a curved line 421, and the characteristic of the inter-stage matching circuit 23 is indicated by a curved line 431. The cut-off frequencies of the characteristics 411, 421, and 431 are arranged to be decremented in the successive order thereof, i.e., the cut-off frequencies of the transistors are arranged to be decremented successively in the direction from the input stage to the output stage of the amplifier.

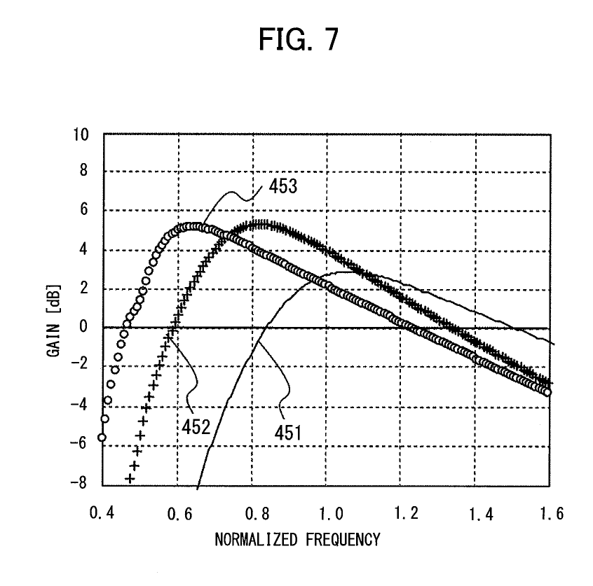

FIG. 7 shows the composite frequency characteristics in combinations of the frequency characteristics of the respective inter-stage matching circuits and transistors in the amplifier according to the first preferred embodiment of the present invention. Reference numeral 451 indicates the composite frequency characteristic formed through combination of the frequency characteristic 411 of the input matching circuit 21 in the amplifier circuit (FIG. 6) and the frequency characteristic 441 of the first stage transistor (FIG. 5). Likewise, reference numeral 452 indicates the composite frequency characteristic formed through combination of the frequency characteristic 421 of the inter-stage matching circuit between the first and second stages of the amplifier circuit (FIG. 6) and the frequency characteristic 442 of the second stage transistor (FIG. 5). Reference numeral 453 indicates the composite frequency characteristic formed through combination of the frequency characteristic 431 of the inter-stage matching circuit between the second and third stages of the amplifier circuit (FIG. 6) and the frequency characteristic 443 of the third stage transistor (FIG. 5).

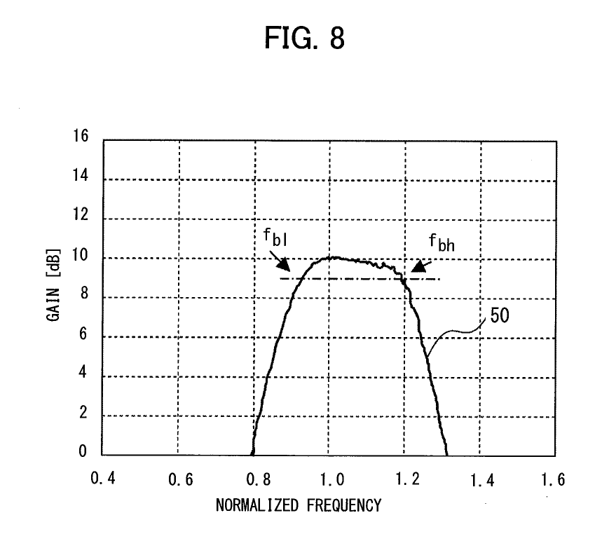

FIG. 8 shows the frequency characteristic with respect to gain of the entire amplifier circuit according to the first preferred embodiment of the present invention. Through combinational use of the matching circuits having the frequency characteristics indicated in FIGS. 6 and 7, it is possible to obtain flatness in gain over a wide bandwidth. That is, as indicated by a composite frequency characteristic 50 in FIG. 8, a bandpass characteristic maintaining a substantially flat gain form in a predetermined frequency range between f_{b1} and f_{bh} can be provided. To be more specific, in a normalized frequency range from 0.9 to 1.2, there is provided a wideband characteristic that maintains a gain ranging from 9.0 dB to 10.0 dB with 30% 1 dB-gain variation band conditioning in fractional bandwidth representation.

Regarding the higher limit frequency f_{bh} of the bandpass characteristic demonstrated in FIG. 8 according to the first preferred embodiment of the present invention, the gain of the composite frequency characteristic 50 decreases steeply in the vicinity of 1.3 that is a normalized frequency level slightly exceeding 1.2. To realize this condition, the frequency characteristic 443 of the third stage transistor 13 among the frequency characteristic of the transistors at the respective stages shown in FIG. 5 is arranged to have a gain value of 0 in the vicinity of a normalized frequency level of 1.3. Likewise, the composite frequency characteristic 453 shown in FIG. 7 is arranged to have a gain value of 0 in the vicinity of a normalized frequency level of 1.2, and the composite frequency characteristic 452 is arranged to have a gain value of 0 in the vicinity of a normalized frequency level of 1.3. Thus, through use of combinations of amplification and attenuation based on difference in maximum oscillating frequency characteristic among the transistors at the respective stages, the gain of the composite frequency characteristic 50 is decreased steeply in the frequency range slightly exceeding the high limit frequency f_{bh} in terms of normalized frequency, thereby realizing a bandpass characteristic in the amplifier circuit. According to the first preferred embodiment of the present invention, a bandpass frequency characteristic with more than 20% 1 dB-gain variation band conditioning in fractional bandwidth representation can be realized in a simple circuit configuration, for example.

As mentioned above, in the microwave and/or millimeter-wave band amplifier circuit according to the first preferred embodiment of the present invention, the gain of the amplifier circuit has a bandpass frequency characteristic. A gain restricting characteristic on the higher frequency side of the bandpass frequency characteristic is implemented based on the frequency characteristic of each transistor proper, and a gain restricting characteristic on the lower frequency side is implemented based on the cut-off frequency of each matching circuit. Thus, according to the first preferred embodiment of the present invention, there is provided a microwave and/or millimeter-wave band amplifier circuit capable of effecting flatness in gain over a wide bandwidth and performing higher-speed device operation without a substantial increase in device size.

In particular, according to the first preferred embodiment of the present invention, a high frequency region which is proximate to the maximum oscillating frequency fₘₐₓ of each transistor and which has a small degree of allowance in terms of performance thereof is used advantageously to set up the higher limit frequency f_{bh} of the bandpass characteristic concerned. Thus, in a simple circuit configuration without using a changeover switch or the like, a higher speed of device operation can be realized while obviating a substantial increase in device size.

### Second Preferred Embodiment

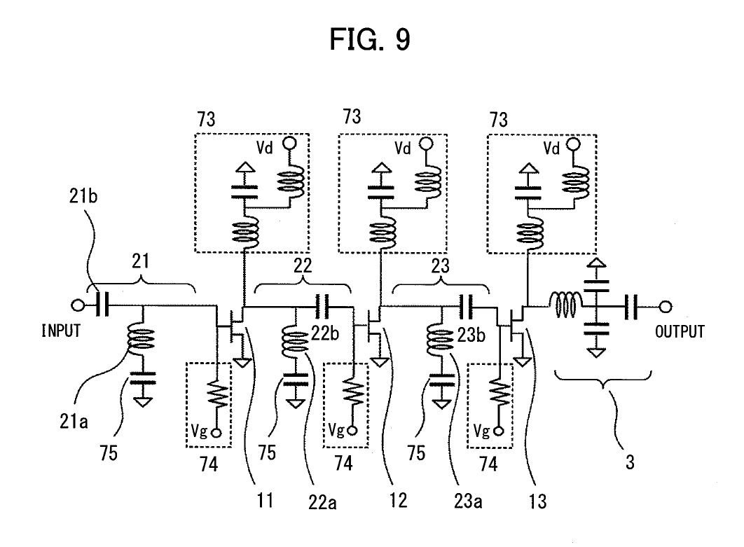

In common practice of designing a microwave and/or millimeter-wave band amplifier circuit, transmission lines such as microstrip lines are used to implement the functionalities of circuit elements in matching circuits for providing a high-pass frequency characteristic. Instead thereof, there may be used inductors. FIG. 9 shows an amplifier circuit according to a second preferred embodiment of the present invention. In the amplifier circuit shown in FIG. 9, inductors 21a, 22a, and 23a are included respectively in an input matching circuit 21 and inter-stage matching circuits 22 and 23 which are equivalent to those demonstrated in the first preferred embodiment of the present invention. These inductors and series capacitors 21b, 22b, and 23b are arranged in combination to provide a high-pass frequency characteristic. By adjusting the circuit elements mentioned above, a bandpass characteristic maintaining a flat gain form in a certain frequency range can be provided in the amplifier circuit.

The gain of the amplifier circuit has a bandpass frequency characteristic also in the second preferred embodiment of the present invention. A gain restricting characteristic on the higher frequency side of the bandpass frequency characteristic is implemented based on the frequency characteristic of each transistor proper, and a gain restricting characteristic on the lower frequency side is implemented based on the cut-off frequency of each matching circuit. Thus, according to the second preferred embodiment of the present invention, there is provided microwave and/or millimeter-wave band amplifier circuit capable of effecting flatness in gain over a wide bandwidth and performing higher-speed device operation without a substantial increase in device size.

### Third Preferred Embodiment

In the present invention, a variety of transistors having different sizes are applicable as plural transistors included in a power amplifier. According to a third preferred embodiment of the present invention, as plural transistors included in the power amplifier thereof, GaAs field-effect transistors are used in such a fashion that the gate widths of the transistors are incremented successively in the direction from input to output.

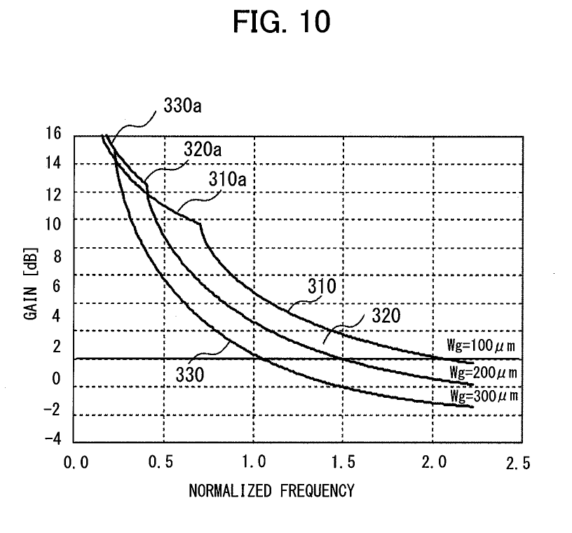

FIG. 10 shows the frequency characteristics with respect to gain values of the GaAs field-effect transistors having different gate widths W_{g}. Reference numeral 310 indicates the frequency characteristic with respect to the maximum available power gain Gₐₘₐₓ of the first stage transistor, reference numeral 320 indicates the frequency characteristic with respect to the maximum available power gain Gₐₘₐₓ of the second stage transistor, and reference numeral 330 indicates the frequency characteristic with respect to the maximum available power gain Gₐₘₐₓ of the third stage transistor. Reference numeral 310a indicates the frequency characteristic with respect to the maximum stable gain Gₘₛ of the first stage transistor, reference numeral 320a indicates the frequency characteristic with respect to the maximum stable gain Gₘₛ of the second stage transistor, and reference numeral 330a indicates the frequency characteristic with respect to the maximum stable gain Gₘₛ of the third stage transistor.

In the third preferred embodiment of the present invention, the gate width W_{g} of the first stage transistor is 100 μm, the gate width W_{g} of the second stage transistor is 200 μm, and the gate width W_{g} of the third stage transistor is 300 μm. That is, the gate widths W_{g} of the transistors used in the amplifier circuit are arranged to be incremented at a ratio of 1:2:3 in the direction from input to output. The other configurational arrangements of the third preferred embodiment of the present invention are similar to those of the first and second preferred embodiments thereof.

The gain of the amplifier circuit has a bandpass frequency characteristic also in the third preferred embodiment of the present invention. A gain restricting characteristic on the higher frequency side of the bandpass frequency characteristic is implemented based on the frequency of each transistor proper, and a gain restricting characteristic on the lower frequency side is implemented based on the cut-off frequency of each matching circuit.

Thus, according to the third preferred embodiment of the present invention, there is provided a microwave and/or millimeter-wave band amplifier circuit capable of effecting flatness in gain over a wide bandwidth and performing higher-speed device operation without a substantial increase in device size.

### Fourth Preferred Embodiment

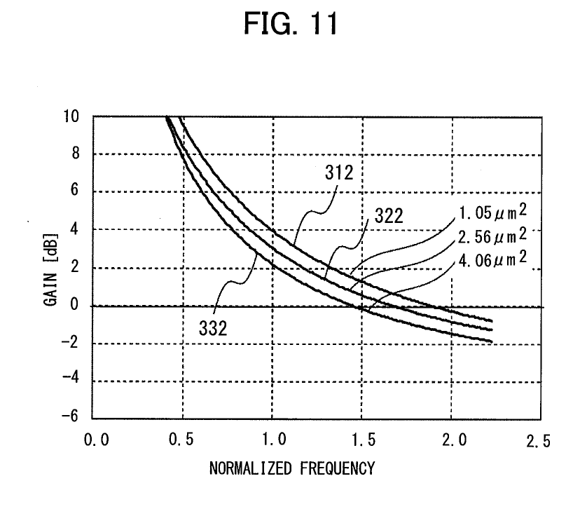

According to a fourth preferred embodiment of the present invention, as plural transistors included in the power amplifier thereof, SiGe bipolar transistors are used in such a fashion that the emitter areas of the transistors are incremented successively in the direction from input to output. FIG. 11 shows the frequency characteristics with respect to gain values of SiGe bipolar transistors having different emitter areas. Reference numeral 312 indicates the frequency characteristic with respect to the maximum available power gain Gₐₘₐₓ of the first stage transistor, reference numeral 322 indicates the frequency characteristic of the maximum available power gain Gₐₘₐₓ of the second stage transistor, and reference numeral 332 indicates the frequency characteristic of the maximum available power gain Gₐₘₐₓ of the third stage transistor. In the fourth preferred embodiment of the present invention, the emitter area of the first stage transistor is 1.05 μm², the emitter area of the second stage transistor is 2.56 μm², and the emitter area of the third stage transistor is 4.06 μm². The other configurational arrangements of the fourth preferred embodiment of the present invention are similar to those of the first and second preferred embodiments thereof.

The gain of the amplifier circuit has a bandpass frequency characteristic also in the fourth preferred embodiment of the present invention. A gain restricting characteristic on the higher frequency side of the bandpass frequency characteristic is implemented based on the frequency of each transistor proper, and a gain restricting characteristic on the lower frequency side is implemented based on the cut-off frequency of each matching circuit.

Thus, according to the fourth preferred embodiment of the present invention, there is provided a microwave and/or millimeter-wave band amplifier circuit capable of effecting flatness in gain over a wide bandwidth and performing higher-speed device operation without a substantial increase in device size.

### Fifth Preferred Embodiment

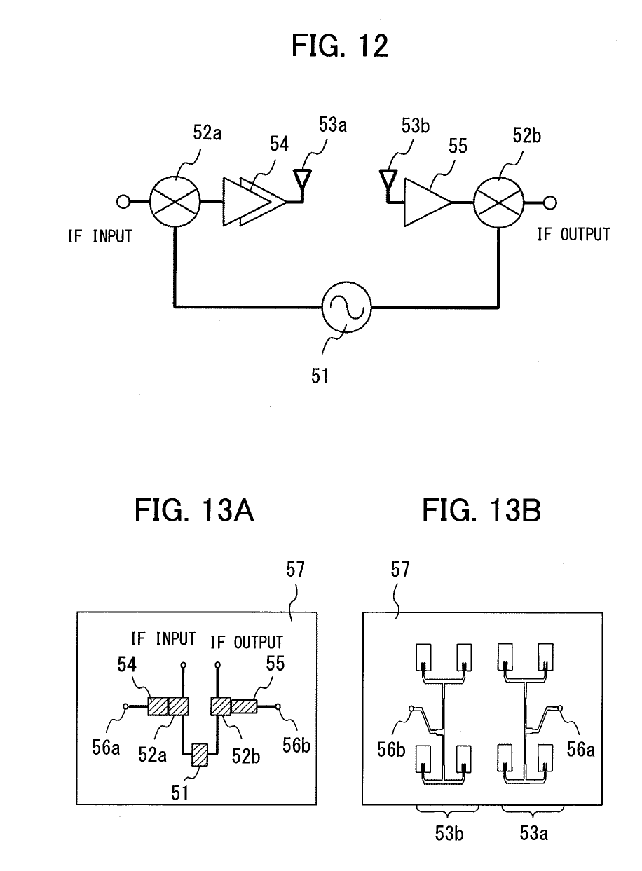

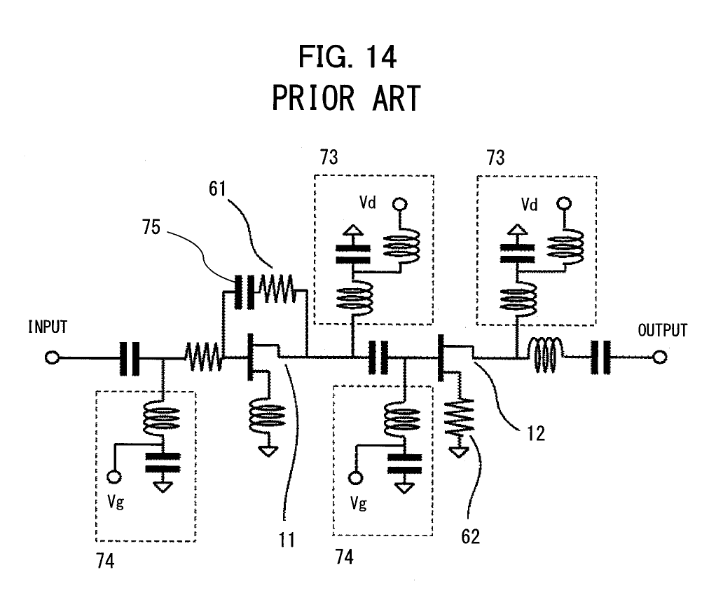

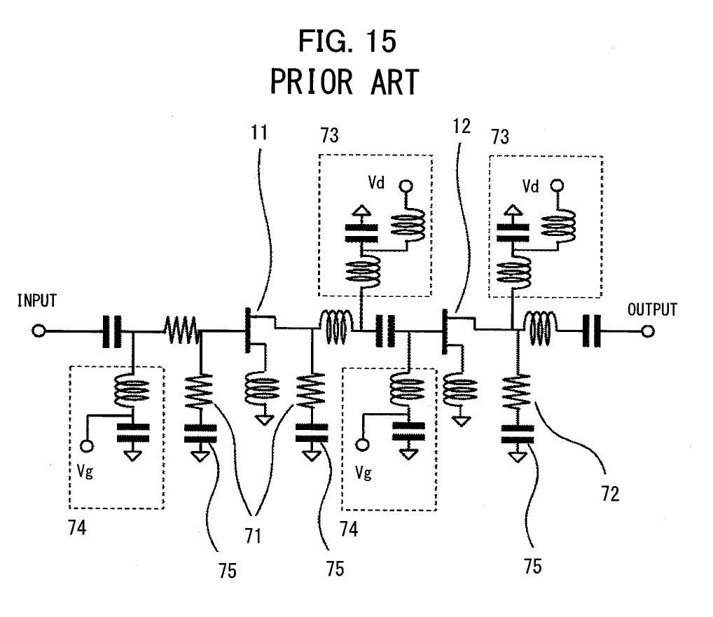

The microwave and/or millimeter-wave band amplifier circuit according to the present invention is applicable as a transmission signal amplifying component device in a millimeter-wave transceiver (wireless transmitter-receiver system) shown in FIG. 12. In FIGS. 13A and 13B, there is illustrated an exemplary RF module including the millimeter-wave transceiver shown in FIG. 12.

Referring to FIG. 12, the millimeter-wave transceiver includes an oscillator 51, a transmitting circuit section, and a receiving circuit section. The transmitting circuit section includes a transmitting mixer 52a, a transmitting amplifier 54, and a transmitting antenna 53a. The receiving circuit section includes a receiving antenna 53b, a receiving low-noise amplifier 55, and a receiving mixer 52b. One of the amplifiers described in the explanation of the first to fourth preferred embodiments of the present invention is used as the transmitting amplifier 54 in the fifth preferred embodiment thereof. More specifically, the transmitting amplifier 54 includes “n” stages of amplifier circuits wherein multiple-stage transistors having different sizes incremented successively in the direction from input to output are arranged in cascade connection. In the transmitting amplifier 54, plural matching circuits are designed to provide a high-pass frequency characteristic. The cut-off frequencies f₁, f₂, . . . , and fₙ (low band cut-off frequencies) are arranged to be decremented successively in the direction from input to output. The gain of the amplifier circuit has a bandpass frequency characteristic. A gain restricting characteristic on the higher frequency side of the bandpass frequency characteristic is implemented based on each of the transistors proper, and a gain restricting characteristic on the lower frequency side is implemented based on the cut-off frequency of each matching circuit.

In a specific exemplary application of the millimeter-wave transceiver (wireless transmitter-receiver system) according to the fifth preferred embodiment of the present invention, it is assumed to adopt the unlicensed high-speed wireless communication standard IEEE802.15.3c that allows the use of a frequency band of 59 GHz to 66 GHz in Japan. In operation of the millimeter-wave transceiver, a high frequency signal generated by the oscillator 51 is used as a local signal for the transmitting mixer 52a and the receiving mixer 52b. After mixed with an IF input signal, the high frequency signal is transmitted from the transmitting antenna 53a through the transmitting amplifier 54. On the other hand, a signal transmitted from another millimeter-wave transceiver is received by the receiving antenna 53b, and the signal thus received is input to the receiving mixer 52b through the receiving low-noise amplifier 55. In the receiving mixer 52b, the signal received is mixed with the local signal to produce an IF output signal.

Referring to FIGS. 13A and 13B, there is illustrated an exemplary RF module including the millimeter-wave transceiver shown in FIG. 12. FIG. 13A shows the front side of a dielectric substrate 57 of the RF module, and FIG. 13B shows the back side thereof. On the front side of the dielectric substrate 57, the transmitting amplifier 54, the receiving low-noise amplifier 55, and circuit patterns for coupling these component devices are formed through semiconductor device fabrication process. On the back side of the dielectric substrate 57, the patterns of the transmitting antenna 53a and the receiving antenna 53b are formed through semiconductor device fabrication process. The transmitting amplifier 54 and the transmitting antenna 53a are interconnected by coupling means 56a disposed at a via hole formed through the dielectric substrate 57, and the receiving amplifier 55 and the receiving antenna 53b are interconnected by coupling means 56b disposed at another via hole formed through the dielectric substrate 57. The transistors included in the transmitting amplifier 54 formed on the dielectric substrate 57 are of the same type, e.g., field-effect transistors only or bipolar transistors only.

In the millimeter-wave transceiver described above, the transmitting amplifier 54 thereof can effect flatness in gain over a wide bandwidth without using a changeover switch or the like. Hence, according to the fifth preferred embodiment of the present invention, there is provided a small-type millimeter-wave transceiver having a microwave and/or millimeter-wave band amplifying function for meeting the requirement for higher-speed device operation. In particular, since a sufficient degree of flat gain can be obtained over a wide bandwidth even in a frequency region having a small degree of allowance in terms of transistor performance, it is possible to provide a millimeter-wave transceiver equipped with an amplifier having satisfactory performance in the entire frequency range used for communication equipment and radar system applications. For example, the use of the millimeter-wave transceiver of the present invention as a wireless HDMI terminal can realize wireless image transmission with low delay and high image quality, i.e., cableless non-compression transmission of TV pictures and game images.

It is to be noted that the transistors included in the transmitting amplifier 54 may be of different types in combination. For example, the type of the first and second stage transistors may be different from that of the last stage transistor.

The present invention may be embodied in other specific forms without departing from the spirit or essential characteristics thereof. The preferred embodiments described herein are therefore to be considered in all respects as illustrative and not restrictive, the scope of the invention being indicated by the appended claims rather than by the foregoing description, and all changes which come within the meaning and range of equivalency of the claims are therefore intended to be embraced therein.

What is claimed is:

1. An amplifier circuit suitable for amplifying at least either microwave band signal or millimeter-wave band signal, the amplifier circuit comprising:
a plurality of transistors disposed at a plurality of stages in a direction from input to output; and
a plurality of matching circuits for coupling the transistors in cascade connection,
wherein the transistors each have different maximum oscillating frequencies,
wherein the sizes of the transistors are arranged to be incremented successively in the direction from input to output,
wherein each of the matching circuits for coupling the transistors provides a high-pass frequency characteristic,
wherein the matching circuits being arranged in a fashion that each of a low band cut-off frequency of the high-pass frequency characteristic thereof is decremented successively in the direction from input to output,
wherein a gain in the amplifier circuit has a bandpass frequency characteristic, and
wherein a gain restricting characteristic on the higher frequency side of the bandpass frequency characteristic is implemented based on a frequency characteristic of each of the transistors, and a gain restricting characteristic on the lower frequency side thereof is implemented based on the cut-off frequency of each of the matching circuits.

2. The amplifier circuit according to claim 1,
wherein the bandpass frequency characteristic provides a substantially flat gain form in a frequency range between a maximum oscillating frequency of the transistor at the last stage and a maximum stable operating frequency of the transistor at the first stage.

3. The amplifier circuit according to claim 1,
wherein the bandpass frequency characteristic provides a substantially flat gain form in a frequency range between a maximum oscillating frequency of the transistor at the last stage and a minimum cut-off frequency of the matching circuit on the output side.

4. The amplifier circuit according to claim 3,
wherein a higher limit frequency characteristic with respect to the flat gain form of the bandpass frequency characteristic is provided by a composite frequency characteristic formed through combination of frequency characteristics of the transistors and frequency characteristics of the matching circuits.

5. The amplifier circuit according to claim 3,
wherein a higher limit frequency characteristic with respect to the flat gain form of the bandpass frequency characteristic is provided through combinational use of amplification and attenuation based on difference in maximum oscillating frequency characteristic among the transistors.

6. The amplifier circuit according to claim 5,
wherein the amplifier circuit includes at least three stages of transistors, an input matching circuit, and a plurality of inter-stage matching circuits for coupling the transistors at adjacent stages, and
wherein the higher limit frequency characteristic with respect to the flat gain form of the bandpass frequency characteristic is provided by an overall composite frequency characteristic formed through combination of a composite frequency characteristic including a frequency characteristic of the input matching circuit and a frequency characteristic of the transistor at the first stage, a composite frequency characteristic including frequency characteristics of the inter-stage matching circuits at the first and second stages and a frequency characteristic of the transistor at the second stage, and subsequent composite frequency characteristics including each combination of frequency characteristics of the inter-stage matching circuits at the second and subsequent stages and frequency characteristics of the transistor at the third and subsequent stages.

7. The amplifier circuit according to claim 1,
wherein each of the matching circuits having the high-pass frequency characteristic comprises a series-connected capacitor element and a ground-connected transmission line.

8. The amplifier circuit according to claim 1,
wherein each of the matching circuits having the high-pass frequency characteristic comprises a series-connected capacitor element and a ground-connected spiral inductor.

9. The amplifier circuit according to claim 1,
wherein an input terminal and an output terminal of the amplifier circuit are arranged for matching with an arbitrary characteristic impedance value.

10. The amplifier circuit according to claim 1,
wherein the amplifier circuit includes an input matching circuit, three stages of transistors, two inter-stage matching circuits for coupling the transistors, and an output matching circuit.

11. The amplifier circuit according to claim 10,
wherein the output matching circuit is of a high-pass frequency characteristic type having a cut-off frequency thereof arranged to be lower than a cut-off frequency of each inter-stage matching circuit.

12. The amplifier circuit according to claim 2,
wherein the bandpass frequency characteristic has more than 20% 1 dB-gain variation band conditioning in fractional bandwidth representation.

13. The amplifier circuit according to claim 3,
wherein the bandpass frequency characteristic has more than 20% 1 dB-gain variation band conditioning in fractional bandwidth representation.

14. An amplifier circuit suitable for amplifying at least either microwave band signal or millimeter-wave band signal, the amplifier circuit comprising:
a plurality of transistors fabricated through the same kind of process, the transistors being disposed at a plurality of stages in a direction from input to output; and
a plurality of matching circuits for coupling the transistors in cascade connection,
wherein the transistors each have different maximum oscillating frequencies,
wherein the sizes of the transistors are arranged to be incremented successively in the direction from input to output,
wherein each of the matching circuits for coupling the transistors provides a high-pass frequency characteristic,
wherein the matching circuits being arranged in a fashion that each of a low band cut-off frequency of the high-pass frequency characteristic thereof is decremented successively in the direction from input to output,
wherein a gain in the amplifier circuit has a bandpass frequency characteristic, and
wherein a gain restricting characteristic on the higher frequency side of the bandpass frequency characteristic is implemented based on a frequency characteristic of each of the transistors, and a gain restricting characteristic on the lower frequency side thereof is implemented based on the cut-off frequency of each of the matching circuits.

15. The amplifier circuit according to claim 14,
wherein the transistors included in the amplifier circuit are field-effect transistors.

16. The amplifier circuit according to claim 15,
wherein the amplifier circuit includes three stages of field-effect transistors, an input matching circuit, and two inter-stage matching circuits for coupling the transistors at adjacent stages, and
wherein the sizes of the transistors at the three stages are arranged to be incremented at a ratio of substantially 1:2:3 in the direction from input to output.

17. The amplifier circuit according to claim 14,
wherein the transistors included in the amplifier circuit are bipolar transistors.

18. A millimeter-wave transceiver comprising:
an oscillator;
a transmitting circuit section; and
a receiving circuit section,
wherein the transmitting circuit section includes a transmitting amplifier for amplifying an output signal of a transmitting mixer and feeding the amplified output signal to a transmitting antenna,
wherein the transmitting amplifier is provided as an amplifier circuit comprising a plurality of transistors disposed at a plurality of stages in a direction from input to output, and a plurality of matching circuits for coupling the transistors in cascade connection, wherein the transistors each have different maximum oscillating frequencies,
wherein the sizes of the transistors are arranged to be incremented successively in the direction from input to output,
wherein each of the matching circuits for coupling the transistors provides a high-pass frequency characteristic,
wherein the matching circuits being arranged in a fashion that each of a low band cut-off frequency of the high-pass frequency characteristic thereof is decremented successively in the direction from input to output,
wherein a gain in the amplifier circuit has a bandpass frequency characteristic, and
wherein a gain restricting characteristic on the higher frequency side of the bandpass frequency characteristic is implemented based on a frequency characteristic of each of the transistors, and a gain restricting characteristic on the lower frequency side thereof is implemented based on the cut-off frequency of each of the matching circuits.

19. The millimeter-wave transceiver according to claim 18,
wherein the bandpass frequency characteristic provides a substantially flat gain form in a frequency a maximum oscillating frequency of the transistor at the last stage and a minimum cut-off frequency of the matching circuit on the output side, and
wherein the higher limit characteristic with respect to the flat gain form of the bandpass frequency characteristic is provided by a composite frequency characteristic formed through combination of frequency characteristics of the transistors and frequency characteristics of the matching circuits.

20. The millimeter-wave transceiver according to claim 18,
wherein, on the front side of a dielectric substrate, there are formed the transmitting amplifier, a receiving low-noise amplifier, and circuit patterns for coupling arrangements thereof, and on the back side of the dielectric substrate, there are formed patterns of a transmitting antenna coupled to the transmitting amplifier and a receiving antenna coupled to the receiving low-noise amplifier.
